(19) United States
(12) Patent Application Publication
(10) Pub. No.: US 2025/0006826 A1
(43) Pub. Date: Jan. 2, 2025

(54) SEMICONDUCTOR DEVICE WITH SEMICONDUCTOR CARBON NANOTUBE AND MANUFACTURING METHOD THEREOF

(71) Applicant: NANYA TECHNOLOGY CORPORATION, New Taipei City (TW)

(72) Inventor: Wei-Chuan FANG, New Taipei City (TW)

(21) Appl. No.: 18/214,662

(22) Filed: Jun. 27, 2023

(51) Int. Cl. H01L 29/775; H01L 29/12; H01L 29/49; H01L 29/66

(52) U.S. Cl. CPC H01L 29/775; H01L 29/125; H01L 29/4908; H01L 29/66045

(57) ABSTRACT

A semiconductor device includes a substrate, a gate electrode in the substrate, a channel region above the gate electrode, a gate dielectric layer between the gate electrode and the channel region, and at least two source/drain regions in contact with the channel region. The channel region includes at least one boron-carbon-nitrogen single-walled nanotube (BCN-SWNT).

### BACKGROUND

### Field of Disclosure

The present disclosure relates to a semiconductor device and manufacturing method thereof.

### Description of Related Art

An integrated circuit (IC) device (also referred to as a semiconductor chip) can contain millions of transistors and other circuit elements that are fabricated on a single silicon crystal substrate (wafer). In recent years, the dimension of the device is scaled down with the further shrinkage of technology node. At the same time, the channel resistance also becomes lower, which gives rise to the possible formation of channel leakage current. Such phenomenon could make the contemporary metal oxide semiconductor field effect transistor channel less available for providing infinitesimal memory cells significantly. Therefore, alternative method for other feasible mechanism compatible with reduced cell geometry is necessary.

### SUMMARY

The present disclosure provides semiconductor device and manufacturing methods thereof to deal with the needs of the prior art problems.

In one or more embodiments, a semiconductor device includes a substrate, a gate electrode in the substrate, a channel region above the gate electrode, a gate dielectric layer between the gate electrode and the channel region, and at least two source/drain regions in contact with the channel region. The channel region includes at least one boron-carbon-nitrogen single-walled nanotube (BCN-SWNT).

In one or more embodiments, the BCN-SWNT includes less than 10 wt % boron and nitrogen atoms.

In one or more embodiments, the BCN-SWNT includes 3 wt % to 5 wt % boron atoms.

In one or more embodiments, the BCN-SWNT includes 3 wt % to 5 wt % nitrogen atoms.

In one or more embodiments, the BCN-SWNT includes 3 wt % to 5 wt % boron atoms and 3 wt % to 5 wt % nitrogen atoms.

In one or more embodiments, the BCN-SWNT includes carbon, boron and nitrogen atoms in sp² hybridization.

In one or more embodiments, the gate dielectric layer includes hafnium dioxide.

In one or more embodiments, a semiconductor device manufacturing method comprising: forming a gate electrode in a substrate; forming a gate dielectric layer over the gate electrode; forming at least one boron-carbon-nitrogen single-walled nanotube (BCN-SWNT) on the gate dielectric layer; and forming at least two source/drain regions in contact with the BCN-SWNT.

In one or more embodiments, the BCN-SWNT includes less than 10 wt % boron and nitrogen atoms.

In one or more embodiments, the BCN-SWNT includes 3 wt % to 5 wt % boron atoms.

In one or more embodiments, the BCN-SWNT includes 3 wt % to 5 wt % nitrogen atoms.

In one or more embodiments, the BCN-SWNT includes 3 wt % to 5 wt % boron atoms and 3 wt % to 5 wt % nitrogen atoms.

In one or more embodiments, the BCN-SWNT includes carbon, boron and nitrogen atoms in sp² hybridization.

In one or more embodiments, the gate dielectric layer includes hafnium dioxide.

In one or more embodiments, the BCN-SWNT is synthesized by chemical vapor deposition (CVD) or laser ablation.

In sum, the semiconductor device and manufacturing method disclosed herein utilizes boron-carbon-nitrogen single-walled nanotube to enhance its semiconductor characteristics and its lower metallic characteristics so as to serve a channel region in a semiconductor transistor device.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a perspective view of a semiconductor transistor device according to some embodiments of the present disclosure;

FIG. 2 illustrates a cross-sectional view of a partial portion in FIG. 1; and

FIG. 3 illustrates a performance diagram for three types of SWNTs according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

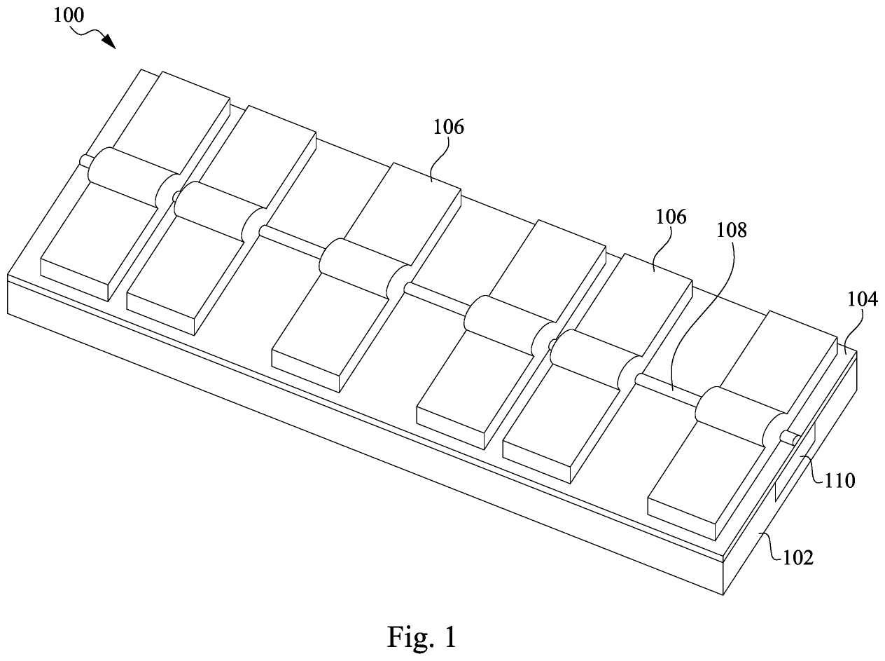

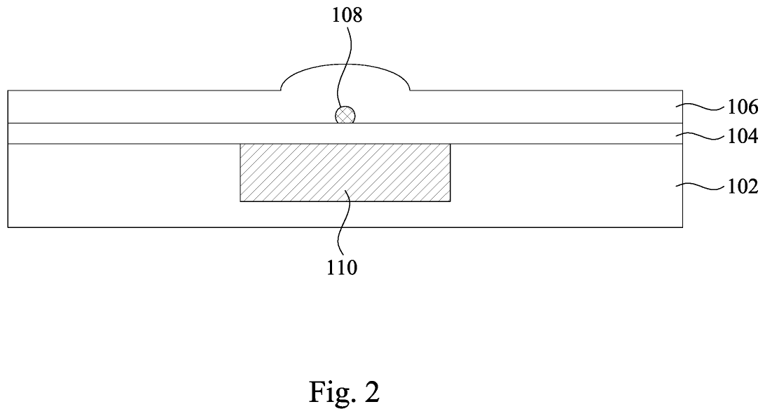

Reference is made to FIGS. 1 and 2, FIG. 1 illustrates a perspective view of a semiconductor transistor device according to some embodiments of the present disclosure, and FIG. 2 illustrates a cross-sectional view of a partial portion in FIG. 1. The perspective view illustrates a semiconductor transistor device 100 using at least one single-walled carbon nanotube (SWCNT) 108 as its channel region. The SWCNT refers to a single layer of graphene rolled into a seamless cylinder, typically with a diameter on the order of a nanometer (10⁻⁹ meters). The length of SWCNT can vary from a few nanometers to several centimeters. They have a high aspect ratio, meaning their length is much greater than their diameter.

The semiconductor transistor device 100 basically includes a semiconductor substrate 102, a gate dielectric layer 104, a gate electrode 110, at least one boron-carbon-nitrogen single-walled nanotube 108 and at least two source/drain regions 106. The gate electrode 110 is a conductor that controls the flow of current through the channel region of the transistor. When a voltage is applied to the gate electrode 110, an electric field is created across the gate dielectric layer 104, which influences the conductivity of the channel region. By modulating the gate voltage, the transistor can control the flow of current through the channel, enabling transistor switching and amplification functionalities.

The gate electrode 110 is typically made of a highly conductive material that allows efficient control of the channel current. Commonly used materials for gate electrodes include doped polysilicon, metal films (such as aluminum or tungsten), or metal silicides (such as titanium silicide or tungsten silicide). In some embodiments of the present disclosure, the gate electrode 110 is formed to be embedded in the semiconductor substrate 102. The materials of the gate electrode 110 is chosen based on its conductivity and compatibility with the fabrication process, is deposited on top of the gate dielectric layer. This can be done using techniques such as physical vapor deposition (PVD), chemical vapor deposition (CVD), or sputtering. Photolithography techniques are employed to define the shape and dimensions of the gate electrode. A photoresist material is applied to the gate electrode layer, exposed to ultraviolet light through a mask, and subsequently developed. The developed photoresist acts as a protective layer for the regions that will remain as the gate electrode. The gate electrode material that is not protected by the developed photoresist is selectively removed using plasma etching or other etching techniques. This step creates the desired gate electrode structure with precise dimensions and alignment. In some cases, the gate electrode material may be doped to enhance its conductivity. Dopants are introduced into the gate electrode layer through ion implantation or diffusion processes. Doping can help improve the overall performance of the transistor. After the gate electrode is formed, contact structures are created to establish electrical connections with the source and drain regions of the transistor. These contacts enable the flow of current through the channel when appropriate voltages are applied.

The gate dielectric layer 104 is an insulating material placed between the gate electrode 110 and the channel region, e.g., the single-walled carbon nanotube 108. The gate dielectric layer 104 serves as an electrical barrier, preventing current flow between the gate electrode and the channel when no voltage is applied. Traditionally, silicon dioxide (SiO₂) has been widely used as the gate dielectric material. However, as transistor dimensions have shrunk, alternative materials with higher dielectric constants, known as high-k dielectrics, have been adopted. Common high-k materials include hafnium dioxide (HfO₂), aluminum oxide (Al₂O₃), zirconium dioxide (ZrO₂), and titanium dioxide (TiO₂). The choice of material depends on factors such as dielectric constant, compatibility with the fabrication process, and desired transistor performance. In some embodiments of the present disclosure, the gate dielectric layer 104 is a hafnium dioxide (HfO₂) coated over the gate electrode 110 and the semiconductor substrate 102. The use of hafnium dioxide (HfO₂) as a gate dielectric has become prevalent in advanced semiconductor technologies, such as CMOS (complementary metal-oxide-semiconductor) transistors, due to its superior electrical properties compared to traditional SiO₂. HfO₂ gate dielectrics enable better gate control, reduced power consumption, improved transistor performance, and enhanced device scalability in modern semiconductor transistors. The gate dielectric layer 104 is typically formed through chemical vapor deposition (CVD), physical vapor deposition (PVD) and atomic layer deposition (ALD). In CVD process, precursor gases are introduced into a reaction chamber, where they undergo chemical reactions to form the desired dielectric material. The gases decompose and deposit as a thin film on the substrate. CVD allows precise control over the thickness and uniformity of the gate dielectric layer. ALD is a deposition technique that involves sequentially exposing the substrate to different precursor gases. Each gas reacts with the surface, depositing a single atomic layer at a time. ALD provides excellent control over film thickness, uniformity, and interface quality. PVD methods, such as sputtering or evaporation, involve the direct deposition of material onto the substrate by physical means. These techniques rely on the vaporization or sputtering of the dielectric material, which condenses onto the substrate as a thin film. After deposition, the gate dielectric layer may undergo annealing or other post-processing steps to improve its properties. Annealing can enhance the dielectric quality, reduce defects, and stabilize the material structure. The thickness of the gate dielectric layer 104 is critical for achieving the desired transistor performance. Advanced technology nodes often require ultra-thin dielectric layers, typically in the range of a few nanometers.

In order to have single-walled carbon nanotube (SWCNT) 108 equipped with semiconductor behavior, a combination of synthesis techniques and post-processing methods can be performed. In some embodiments of the present disclosure, the SWCNT 108 can be a BCN-SWNT (Boron-Carbon-Nitrogen Single-Walled Nanotube) that involves a combination of synthesis techniques and post-processing methods to introduce boron and nitrogen dopants into the carbon nanotube structure. The boron and nitrogen atoms substitute carbon atoms in the graphene lattice of the SWCNTs, forming boron-carbon and nitrogen-carbon covalent bonds. This process alters the electronic structure and properties of the SWCNTs.

SWCNTs can be synthesized using techniques such as chemical vapor deposition (CVD) or laser ablation. The synthesis process involves the growth of carbon nanotubes from carbonaceous precursor gases in the presence of a catalyst.

The first step of CVD method is to prepare the catalyst, which is usually a transition metal catalyst supported on a substrate. Common catalyst materials include iron (Fe), cobalt (Co), nickel (Ni), or their combinations. The catalyst nanoparticles are typically dispersed on a substrate, such as silica, alumina, or magnesium oxide. The catalyst is then activated by a pretreatment process, such as reduction in a hydrogen atmosphere or exposure to other reactive gases. This step helps to create active catalytic sites on the catalyst surface. The catalyst-supported substrate is placed inside a growth chamber, which is then evacuated and purged with inert gases, such as argon or nitrogen, to create a controlled atmosphere. Carbon feedstock gases, such as hydrocarbons (e.g., methane, ethylene, acetylene) or carbon monoxide, are introduced into the growth chamber. The choice of carbon feedstock influences the growth mechanism and the resulting properties of SWCNTs. The growth chamber is heated to a high temperature, typically in the range of 600 to 1000 degrees Celsius. The duration of growth depends on the desired length and density of the SWCNTs. In the presence of the activated catalyst and at the high growth temperature, the carbon feedstock decomposes, and carbon atoms are deposited on the catalyst surface. The carbon atoms then diffuse and form tubular structures, resulting in the growth of SWCNTs.

With respect to laser ablation method, a catalyst material, such as a transition metal, is mixed with a carbon source, typically graphite powder, to create a composite target. The composite target is placed inside a reaction chamber, which is then evacuated or filled with inert gases. A high-power laser is focused onto the target, leading to the vaporization and ablation of the catalyst and carbon source. The vaporized carbon and catalyst species condense and cool down in the reaction chamber, allowing the formation of SWCNTs as the carbon atoms reassemble into tubular structures.

In both CVD and laser ablation methods, the choice of catalyst material and its preparation significantly affect the growth and properties of SWCNT. Commonly used catalysts include iron, cobalt, nickel, or their combinations. The catalyst composition, size, and distribution influence the diameter, chirality, and quality of the synthesized SWCNTs.

There are a few different approaches to introduce boron and nitrogen dopants into the SWCNT structure.

Co-synthesis: During the synthesis process, boron and nitrogen sources can be introduced alongside the carbonaceous precursor gases. By carefully selecting the appropriate boron and nitrogen sources, controlled amounts of boron and nitrogen can be incorporated into the nanotube structure during growth.

Post-synthesis doping: After the synthesis of SWCNTs, post-processing treatments can be applied to introduce boron and nitrogen dopants. For example, the SWCNTs can be exposed to dopant-containing gases or subjected to chemical reactions that incorporate boron and nitrogen atoms into the carbon lattice. This can be achieved through techniques like chemical vapor deposition or plasma treatment.

After the doping step, the BCN-SWNTs need to be characterized and separated from other carbon nanotubes and impurities. Techniques such as density gradient ultracentrifugation, gel-based separation, or size exclusion chromatography can be employed to isolate and purify the BCN-SWNTs based on their properties, such as size or electronic behavior. The synthesized BCN-SWNTs need to be characterized to verify their composition, structure, and properties. Techniques such as transmission electron microscopy (TEM), scanning electron microscopy (SEM), Raman spectroscopy, and X-ray photoelectron spectroscopy (XPS) can be used to analyze the BCN-SWNTs.

In some embodiments of the present disclosure, the BCN-SWNT may include carbon, boron and nitrogen atoms in sp² hybridization. In a carbon nanotube, each carbon atom is bonded to three neighboring carbon atoms in a hexagonal lattice pattern. These bonds are formed through the sharing of electrons, and the electron orbitals involved in bonding are hybridized. In sp² hybridization, three atomic orbitals belonging to the carbon atom combine to form three new hybrid orbitals that are directed towards the corners of a trigonal planar arrangement.

The resulting sp² hybrid orbitals have 33% s-character and 67% p-character, giving rise to a planar structure and allowing the carbon atoms to form strong sigma (o) bonds with their neighboring atoms. These sigma bonds are formed by the overlapping of sp² hybrid orbitals.

In BCN-SWNTs, boron and nitrogen atoms are incorporated into the carbon lattice, introducing additional atoms with different electronic configurations. However, the carbon-carbon bonds within the nanotube still retain the sp² hybridization and resulting sp² bonding.

The sp² bonding in BCN-SWNTs contributes to the unique electronic properties of these nanotubes. It affects the band structure, conductivity, and other characteristics that make BCN-SWNTs potentially useful in semiconductor transistors.

In some embodiments of the present disclosure, the BCN-SWNTs may be manufactured to have less than 10 wt % boron and nitrogen atoms. In some embodiments of the present disclosure, the BCN-SWNTs may be manufactured to have 3 wt % to 5 wt % boron atoms or 3 wt % to 5 wt % nitrogen atoms. In some embodiments of the present disclosure, the BCN-SWNTs may be manufactured to have 3 wt % to 5 wt % boron atoms and 3 wt % to 5 wt % nitrogen atoms.

The source/drain regions 106 are spaced from one another and in contact with the gate dielectric layer 104 and the single-walled carbon nanotube 108. The source/drain regions 106 are manufactured with a series of steps using various techniques. The materials used for the source and drain regions 106 are typically doped silicon. The dopant atoms are introduced into the silicon lattice to modify its electrical properties. The specific dopants used depend on the type of transistor being manufactured. For n-channel transistors, commonly used dopants include phosphorus or arsenic, which introduce additional electrons (n-type doping). For p-channel transistors, boron or indium may be used, which introduce holes (p-type doping).

The source/drain regions 106 may be formed by epitaxial growth to deposit a thin layer of doped silicon onto the gate dielectric layer 104 using techniques like chemical vapor deposition (CVD) or molecular beam epitaxy (MBE). The dopant atoms are incorporated into the growing silicon layer, forming the source and drain regions. After the deposition step, the wafer is subjected to a thermal annealing process. This step is crucial for activating the dopant atoms, repairing any crystal lattice damage caused during deposition, and optimizing the electrical characteristics of the source and drain regions.

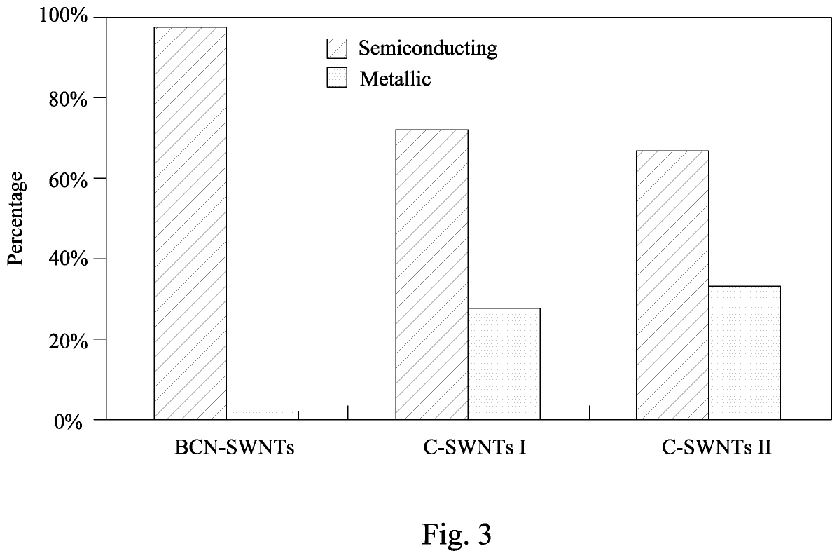

Reference is made to FIG. 3, which illustrates a performance diagram for three types of SWNTs according to some embodiments of the present disclosure. With the BCN-SWNTs, the channel region can be equipped with over 90% semiconductor characteristics and less than 10% metallic characteristics. While the channel regions using conventional Carbon-SWNTs I or Carbon-SWNTs II, the channel region can be equipped with about 60-70% semiconductor characteristics and less than 20-30% metallic characteristics.

In sum, the semiconductor device and manufacturing method disclosed herein utilizes boron-carbon-nitrogen single-walled nanotube to enhance its semiconductor characteristics and its lower metallic characteristics so as to serve a channel region in a semiconductor transistor device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor device comprising:
a substrate;
a gate electrode disposed in the substrate;
a channel region disposed above the gate electrode, wherein the channel region comprises at least one boron-carbon-nitrogen single-walled nanotube (BCN-SWNT);
a gate dielectric layer disposed between the gate electrode and the channel region; and
at least two source/drain regions in contact with the channel region.

2. The semiconductor device of claim 1, wherein the BCN-SWNT comprises less than 10 wt % boron and nitrogen atoms.

3. The semiconductor device of claim 1, wherein the BCN-SWNT comprises 3 wt % to 5 wt % boron atoms.

4. The semiconductor device of claim 1, wherein the BCN-SWNT comprises 3 wt % to 5 wt % nitrogen atoms.

5. The semiconductor device of claim 1, wherein the BCN-SWNT comprises 3 wt % to 5 wt % boron atoms and 3 wt % to 5 wt % nitrogen atoms.

6. The semiconductor device of claim 1, wherein the BCN-SWNT comprises carbon, boron and nitrogen atoms in sp² hybridization.

7. The semiconductor device of claim 1, wherein the gate dielectric layer comprises hafnium dioxide.

8. A semiconductor device manufacturing method comprising:
forming a gate electrode in a substrate;
forming a gate dielectric layer over the gate electrode;
forming at least one boron-carbon-nitrogen single-walled nanotube (BCN-SWNT) on the gate dielectric layer; and
forming at least two source/drain regions in contact with the BCN-SWNT.

9. The method of claim 8, wherein the BCN-SWNT comprises less than 10 wt % boron and nitrogen atoms.

10. The method of claim 8, wherein the BCN-SWNT comprises 3 wt % to 5 wt % boron atoms.

11. The method of claim 8, wherein the BCN-SWNT comprises 3 wt % to 5 wt % nitrogen atoms.

12. The method of claim 8, wherein the BCN-SWNT comprises 3 wt % to 5 wt % boron atoms and 3 wt % to 5 wt % nitrogen atoms.

13. The method of claim 8, wherein the BCN-SWNT comprises carbon, boron and nitrogen atoms in sp² hybridization.

14. The method of claim 8, wherein the gate dielectric layer comprises hafnium dioxide.

15. The method of claim 8, wherein the BCN-SWNT is synthesized by chemical vapor deposition or laser ablation.
